(19) United States
(12) Patent Application Publication
(10) Pub. No.: US 2005/0146449 A1
(43) Pub. Date: Jul. 7, 2005

(54) Mechanism to improve performance monitoring overhead

(76) Inventors: Ali-Reza Adl-Tabatabai, Menlo Park, CA (US); Dong-Yuan Chen, Fremont, CA (US); Anwar M. Ghuloum, Mountain View, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/748,875

(22) Filed: Dec. 30, 2003

(51) Int. Cl. H03M 7/38

(52) U.S. Cl. 341/51

(57) ABSTRACT

In one embodiment, a method is provided. The method of this embodiment provides reading one or more records event data, the one or more event data corresponding to an event monitored from a system; for each event datum, compressing the event datum if the event datum is determined to be compressible; creating a processed event record, the processed event record conforming to a record format; and storing the one or more event data in the processed event record in accordance with the record format.

### FIELD

Embodiments of this invention relate to a mechanism to improve performance monitoring overhead.

### BACKGROUND

Many systems may include a performance monitoring unit (hereinafter “PMU”) to collect events associated with performance of the system. Events may include, for example, instruction cache miss events, data cache miss events, and branch events. Events may be stored as event records, where each event record may include information about the event. Event records may be stored in an event buffer, where they may be made available to one or more client applications, which may use information captured therein to optimize execution of the client application.

Performance monitoring may have overhead, which may limit the optimization that can be achieved by client applications. Overhead may include utilization of resources, such as software and/or hardware. For example, when an event buffer fills up, client applications may be notified. However, notifying client applications may involve expensive inter-process communication that may require, as examples, operating system kernel-mode operations, context switching, and operating system resources Also, the use of event buffers utilized in performance monitoring may also be expensive because event buffers may occupy scarce resources, such as DTLB's (Data Translation Lookaside Buffer), and caches.

### BRIEF DESCRIPTION OF THE DRAWINGS

Embodiments of the present invention are illustrated by way of example, and not by way of limitation, in the figures of the accompanying drawings and in which like reference numerals refer to similar elements and in which:

FIG. 1 illustrates a system.

FIG. 2 illustrates a system embodiment that may be implemented in system of FIG. 1.

FIG. 3 illustrates a method according to one embodiment.

FIG. 4 illustrates a method according to another embodiment.

FIG. 5 illustrates a compressed event record according to one embodiment of the invention.

FIG. 6 illustrates an uncompressed event record according to one embodiment of the invention.

FIG. 7 illustrates characteristics-based compression, and the setting of compression algorithms.

FIG. 8 illustrates an example of characteristics-based compression of an event record.

FIG. 9 illustrates an example of instruction address compression according to one embodiment of the invention.

FIG. 10 illustrates an example of data address compression according to one embodiment of the invention.

FIG. 11 illustrates an example of latency data compression according to one embodiment of the invention.

FIG. 12 illustrates an example of event record processing by a client application.

### DETAILED DESCRIPTION

Embodiments of the present invention include one or more operations, which will be described below. The one or more operations associated with embodiments of the present invention may be performed by hardware components or may be embodied in machine-executable instructions, which when executed may result in a general-purpose or special-purpose processor or circuitry programmed with the machine-executable instructions performing the operations. Alternatively, and/or additionally, some or all of the operations may be performed by a combination of hardware and software. One or more operations that may be described herein may be performed by software and/or hardware components other than those software and/or hardware components described and/or illustrated.

Embodiments of the present invention may be provided, for example, as a computer program product which may include one or more machine-readable media having stored thereon machine-executable instructions that, when executed by one or more machines such as a computer, network of computers, or other electronic devices, may result in the one or more machines carrying out one or more operations in accordance with embodiments of the present invention. A machine-readable medium may include, but is not limited to, floppy diskettes, optical disks, CD-ROMs (Compact Disc-Read Only Memories), magneto-optical disks, ROMs (Read Only Memories), RAMs (Random Access Memories), EPROMs (Erasable Programmable Read Only Memories), EEPROMs (Electrically Erasable Programmable Read Only Memories), magnetic or optical cards, flash memory, or other type of media/machine-readable medium suitable for storing machine-executable instructions.

Moreover, embodiments of the present invention may also be downloaded as a computer program product, wherein the program may be transferred from a remote computer (e.g., a server) to a requesting computer (e.g., a client) by way of one or more data signals embodied in and/or modulated by a carrier wave or other propagation medium via a communication link (e.g., a modem and/or network connection). Accordingly, as used herein, a machine-readable medium may, but is not required to, comprise such a carrier wave.

Examples described below are for illustrative purposes only, and are in no way intended to limit embodiments of the invention. Thus, where examples may be described in detail, or where a list of examples may be provided, it should be understood that the examples are not to be construed as exhaustive, and do not limit embodiments of the invention to the examples described and/or illustrated.

Introduction

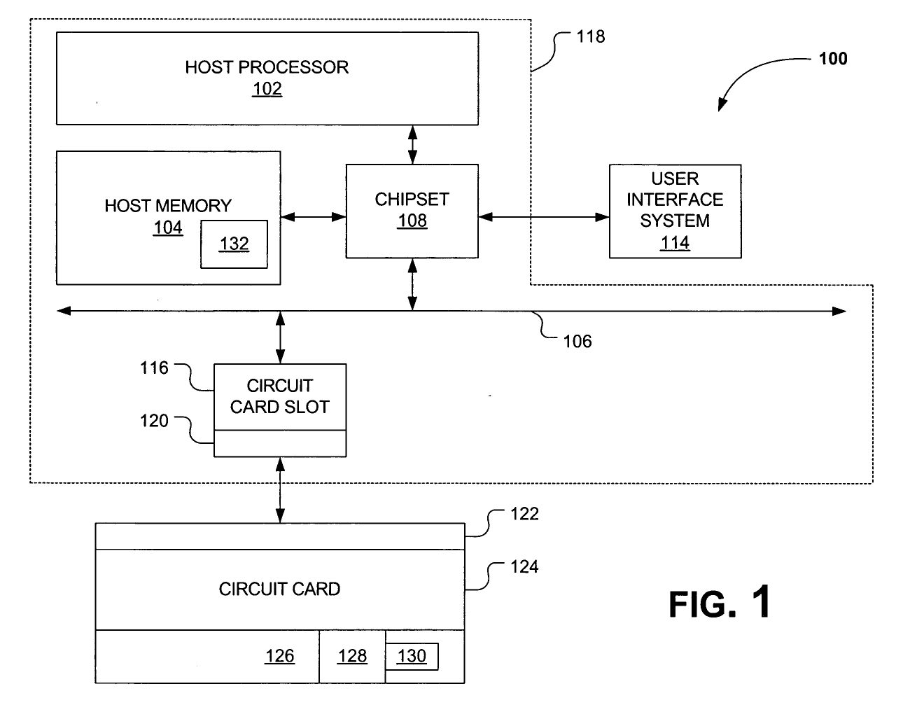

FIG. 1 illustrates a system. System 100 may comprise host processor 102, host memory 104, bus 106, and chipset 108. Host processor 102 may comprise, for example, an Intel® Itanium® microprocessor that is commercially available from the Assignee of the subject application. Of course, alternatively, host processor 102 may comprise another type of microprocessor, such as, for example, a microprocessor that is manufactured and/or commercially available from a source other than the Assignee of the subject application, without departing from this embodiment.

Host processor 102 may be communicatively coupled to chipset 108. As used herein, a first component that is “communicatively coupled” to a second component shall mean that the first component may communicate with the second component via wirelined (e.g., copper wires), or wireless (e.g., radio frequency) means. Chipset 108 may comprise a host bridge/hub system that may couple host processor 102, host memory 104, and a user interface system 114 to each other and to bus 106. Chipset 108 may also include an I/O bridge/hub system (not shown) that may couple the host bridge/bus system 108 to bus 106. Chipset 108 may comprise one or more integrated circuit chips, such as those selected from integrated circuit chipsets commercially available from the Assignee of the subject application (e.g., graphics memory and I/O controller hub chipsets), although other one or more integrated circuit chips may also, or alternatively, be used. User interface system 114 may comprise, e.g., a keyboard, pointing device, and display system that may permit a human user to input commands to, and monitor the operation of, system 100.

Bus 106 may comprise a bus that complies with the Peripheral Component Interconnect (PCI) Local Bus Specification, Revision 2.2, Dec. 18, 1998 available from the PCI Special Interest Group, Portland, Oreg., U.S.A. (hereinafter referred to as a “PCI bus”). Alternatively, bus 106 instead may comprise a bus that complies with the PCI-X Specification Rev. 1.0a, Jul. 24, 2000, available from the aforesaid PCI Special Interest Group, Portland, Oreg., U.S.A. (hereinafter referred to as a “PCI-X bus”). Also, alternatively, bus 106 may comprise other types and configurations of bus systems.

Host processor 102, host memory 104, bus 106, chipset 108, and circuit card slot 116 may be comprised in a single circuit board, such as, for example, a system motherboard 118. Circuit card slot 116 may comprise a PCI expansion slot that comprises a PCI bus connector 120. PCI bus connector 120 may be electrically and mechanically mated with a PCI bus connector 122 that is comprised in circuit card 124. Circuit card slot 116 and circuit card 124 may be constructed to permit circuit card 124 to be inserted into circuit card slot 116. When circuit card 124 is inserted into circuit card slot 116, PCI bus connectors 120, 122 may become electrically and mechanically coupled to each other. When PCI bus connectors 120, 122 are so coupled to each other, circuitry 126 in circuit card 124 may become electrically coupled to bus 106.

System 100 may comprise one or more memories to store machine-executable instructions 130, 132 capable of being executed, and/or data capable of being accessed, operated upon, and/or manipulated by processor, such as host processor 102, and/or circuitry, such as circuitry 126. Such one or more memories may include host memory 104, and memory 128 in circuitry 126, for example. One or more memories may comprise read only, mass storage, and/or random access computer-readable memory. The execution of program instructions 130, 132 and/or the accessing, operation upon, and/or manipulation of this data by the processor 102 and/or circuitry 126 may result in, for example, processor 102 and/or circuitry 126 carrying out some or all of the operations described herein.

Circuitry 126 refers to one or more circuits to implement one or more operations. Circuitry 126 may be programmed with machine-executable instructions to perform the one or more operations. Additionally, circuitry 126 may comprise memory 128 that may store, and/or be programmed with instructions 130 to perform the one or more operations. In either case, these program instructions, when executed, may result in some or all of the operations described in the blocks of the methods herein being carried out. Circuitry 126 may comprise one or more digital circuits, one or more analog circuits, a state machine, programmable circuitry, and/or one or more ASIC's (application specific integrated circuits).

Instead of being comprised in circuit card 124, some or all of circuitry 126 may be comprised in other structures, systems, and/or devices that may be, for example, comprised in motherboard 118, coupled to bus 106, and exchange data and/or commands with other components in system 100. For example, chipset 108 may comprise one or more integrated circuits that may comprise circuitry 126. Additionally, system 100 may include a plurality of cards, identical in construction and/or operation to circuit card 124, coupled to bus 106 via a plurality of circuit card slots identical in construction and/or operation to circuit card slot 116.

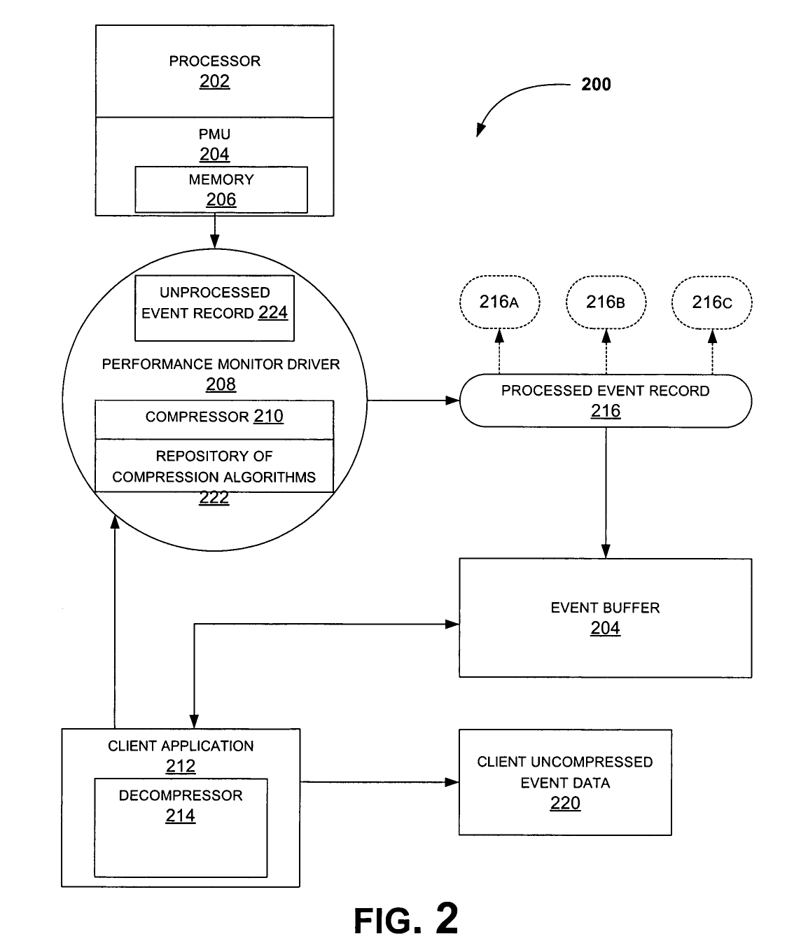

FIG. 2 illustrates a system embodiment 200 of the invention that may be implemented in one or more components of system 100. System 200 may include processor 202, PMU (performance monitor unit) 204, memory 206, performance monitor driver 208, compressor 210, event buffer 204, and decompressor 214. System 200 is not limited to the components illustrated, and is not limited to the number of components illustrated. For example, system 200 may include a plurality of processors 202, and/or other components, without departing from embodiments of the invention.

Processor 202 may be a processor, such as host processor 102. Processor 202 may include PMU 204 to monitor system 200 for one or more events, and to collect the one or more events in memory 206. An “event” as used herein, refers to acts associated with performance of a system, such as system 100, or system 200. For example, an event may comprise an instruction cache miss event, a data cache miss event, or a branch event. An instruction cache miss event refers to the execution of a program instruction that may result, at least in part, in a miss in an instruction cache. A data cache miss event refers to a data access that may result, at least in part, in a cache miss. A branch event may record the outcome of the execution of a branch instruction. A sequence of consecutive branch events may be recorded by PMU 204 to, forming a program path profile, also known as (or a branch trace). Other types of events, of course, are possible. However, these types of events will be further described and/or illustrated.

Each event may be associated with data about the event (hereinafter referred to as “event data”). Event data may comprise, for example, the address of an instruction, the execution of which may result, at least in part, in a cache miss in an instruction cache miss event or a data cache miss event; the address of an accessed memory location that missed in a data cache miss event; latency data of an instruction cache miss event or a data cache miss event; and a branch address and target address in a branch event.

Client application 212 may request performance monitoring services from PMU 204 to monitor system 200 for one or more events. Client application 212 may reside with system 200, or on some other system, which may be similar in construction to, and may operate similarly as, system 100. “Client application” refers to any program or device that may use event data. In one embodiment, client application 212 may use event data to improve, or to optimize its own performance. Client application 212 may comprise, for example, a compiler (such as a dynamic compiler, or a static compiler that performs profile-guided optimizations, e.g., Intel® Electron™ and Proton™ compilers, commercially available through the Assignee of the subject application); a dynamic binary translation system (e.g., Intel® IA32 execution layer software, which executes IA-32 binaries in an Itanium® processor using dynamic binary translation, commercially available through the Assignee of the subject application); a managed runtime environment (e.g., Java™ Virtual Machines commercially available from Sun Microsystems™, and CLR™—Common Language Runtime—execution environment commercially available from Microsoft® Corporation); a performance visualization tool (e.g., Intel® VTune™ analyzer, commercially available through the Assignee of the subject application); and a static post-link binary optimizer (e.g., Spike™ commercially available from Compaq, a subsidiary of Hewlett-Packard Development Company, LP).

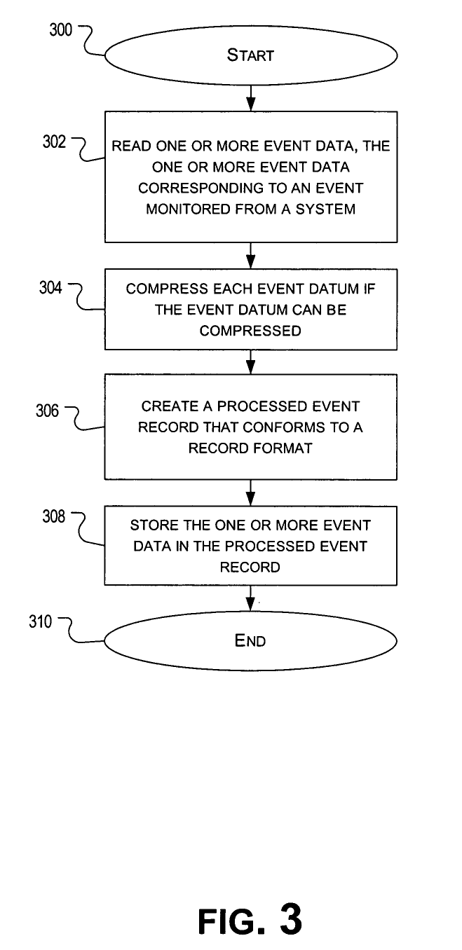

FIG. 3 is a flowchart illustrating a method according to one embodiment. The method begins at block 300, and continues to block 302, where performance monitor driver 208 may read one or more event data, where the one or more event data may each correspond to an event monitored from system 200. At block 304, compressor 210 may compress each event datum if the event datum is determined to be compressible. In one embodiment, compressor 210 may compress the event data using a compression algorithm selected from a repository of compression algorithms 222.

At block 306, performance monitor driver 208 may create a processed event record 216 that conforms to a record format. In one embodiment, a processed event record 216 may correspond to an unprocessed event record. An “unprocessed event record” refers to an event record that has not been processed, such as by compressor 210. An unprocessed event record may be created for each event by performance monitor driver 208, and may comprise a set of fields to hold unprocessed event data. “Unprocessed event data” may comprise uncompressed event data. A “processed event record” refers to an event record that has been processed, and may comprise a set of fields to hold processed event data. In embodiments of the invention, a compressor 210 may process an event record by attempting to compress the one or more fields in the event record. Therefore, depending on whether compressor 210 is successful or unsuccessful, “processed event data” may comprise uncompressed event data, compressed event data, or both. Processed event record 216 may be created in accordance with a record format. In embodiments of the invention, a record format may comprise a compressed record format having compressed event data, an uncompressed record format having uncompressed event data, or a hybrid record format having both uncompressed and compressed event data. Other record formats are possible. In embodiments of the invention, therefore, processed event record 216 may comprise compressed event record 216A in a compressed record format, uncompressed event record 216B in an uncompressed record format, or hybrid event record 216C in a hybrid record format, as examples.

At block 308, performance monitor driver 208 may store one or more event data in processed event record 216. The method ends at block 310. Performance monitor driver 208 may store processed event record 216 in event buffer 204. Client application may access one or more processed event records 216 from event buffer 204.

PMU 204 and performance monitor driver 208 may each be embodied in machine-executable instructions, such as machine-executable instructions 130, 132 that may be executed by processor 202, such as host processor 102, and/or circuitry, such as circuitry 126. Alternatively, PMU 204 and performance monitor driver 208 may individually or together be embodied as hardware and/or firmware in circuitry, such as circuitry 126. Memory 206 and event buffer 204 may each comprise memory such as memory 104, 128. For example, memory 206 may be one or more registers of a processor, such as processor 202, and event buffer 204 may be a temporary memory.

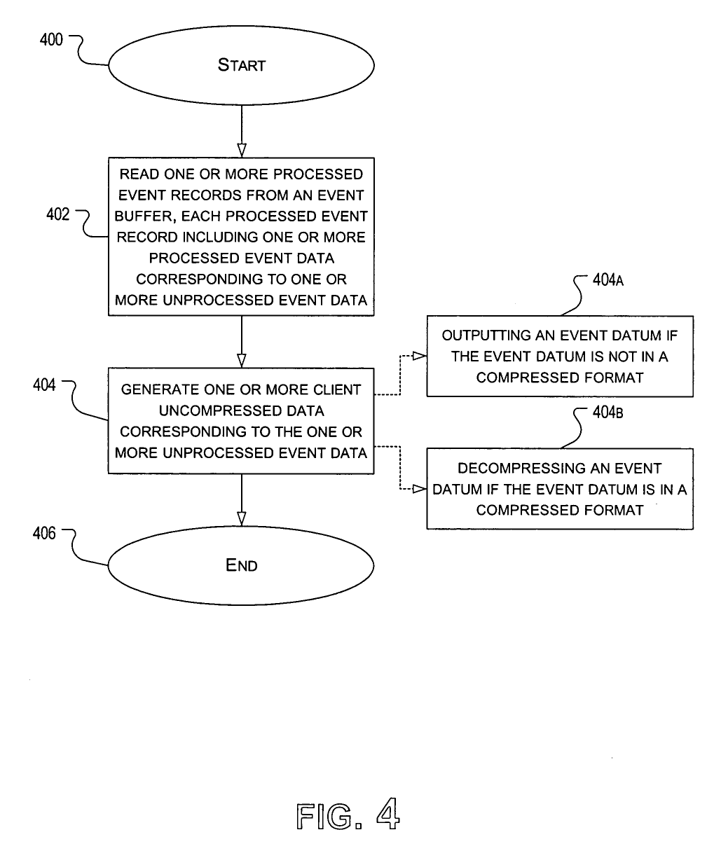

FIG. 4 is a flowchart illustrating a method according to another embodiment. The method begins at block 400, and continues to block 402 where one or more client applications 212 may read one or more processed event records 216 from event buffer 204, each processed event record 216 including one or more processed event data corresponding to one or more unprocessed event data. At block 404, client application 212 may generate client uncompressed event data 220 corresponding to the one or more uncompressed event data. Generating one or more client uncompressed event data may include outputting an event datum if the event datum is not in a compressed format 404A, or decompressing an event datum if the event datum is in a compressed format 404B. The method ends at block 406. Client application 212 may use decompressor 214 to decompress compressed event data. Decompressor 214 may be local to each client application 212, where each client application 212 may have its own decompressor 214. Alternatively, decompressor 214 may be global with respect to each client application 212, where decompressor 214 may decompress event data for the one or more client applications 212.

“Client uncompressed event data” refers to uncompressed event data that client application 212 may output (or that client application 212 may use internally), as opposed to “uncompressed event data” from unprocessed event record 224 that PMU 204 may output, and/or from processed event record 216 that performance monitor driver 208 may output. Client uncompressed event data 220 may correspond to uncompressed event data from unprocessed event record 224. Client uncompressed event data 220 may be the result of decompressing compressed data in processed event record 216, or it may be the result of reading uncompressed data directly from processed event record 216. Client uncompressed event data 220 may ultimately be used by client application 212 to improve its performance, for example.

Creating An Event Record

One or more event data may be stored in a processed event record 216 in accordance with a record format. In one embodiment, if compressor 210 successfully compresses the one or more event data in uncompressed event record 224, then performance monitor driver 208 may create a compressed event record 216A in which each event datum may be stored in a compressed format in the compressed event record 216A. Likewise, if compressor 210 unsuccessfully compresses one or more of the event data in an event record, then performance monitor driver 208 may create an uncompressed event record 216B in which each event data may be stored in an uncompressed format in uncompressed event record 216B.

Other record formats are possible. For example, performance monitor driver 208 may alternatively create a hybrid event record 216C. A hybrid event record 216C may be created if one or more event data is determined not to be compressible, and one or more event data is determined to be compressible. Event data that is determined to be compressible are stored in a compressed format, and event data that is determined not to be compressible are stored in an uncompressed format in hybrid event record 216C.

Since event data may differ for different types of events, event record layouts may differ as well. An “event record layout” refers to an arrangement of processed event record 216, including the type and size of fields used. For example, processed event record 216 for an instruction cache miss event may correspond to an event record layout comprising a 10-bit instruction address field, and a 2-bit latency field, and an event record for a data cache miss event may correspond to an event record layout comprising a 10-bit instruction address field, a 19-bit data address field, and a 2-bit latency field. In one embodiment, for example, instruction cache miss events and data cache miss events may use event records 500, 600 having the same event record layout. Since instruction cache miss events may not comprise a data address, the data address field may remain empty, for example.

Each client application 212 may communicate an event record layout to performance monitor driver 208, and performance monitor driver 208 may create processed event record 216 in accordance with client application's 212 event record layout.

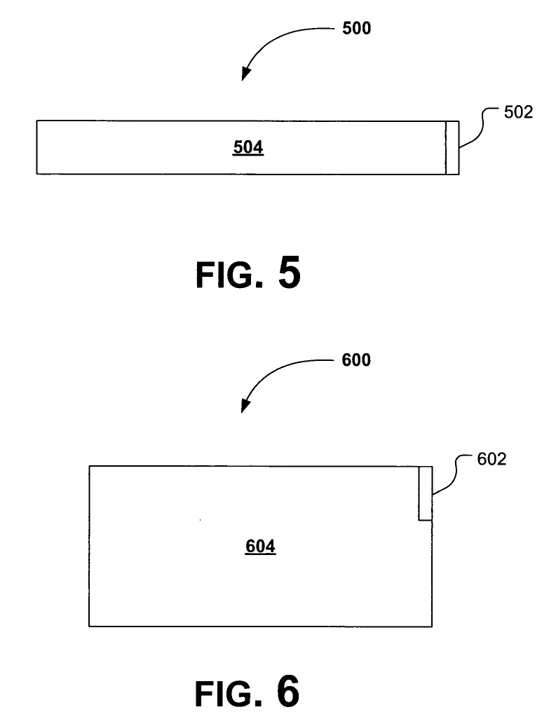

In one exemplary embodiment, as illustrated in FIG. 5, compressed event record 216A may have an event record layout 500 that may comprise a 1-bit compression field 502 (set to “1”, for example) to indicate that the event record is compressed, and one or more other fields 504 of one or more sizes, M, to store compressed event data. FIG. 6 illustrates an uncompressed event record 216B having an event record layout 600 that may comprise a 1-bit compression field 602 (set to “0”, for example) to indicate that the event record is uncompressed, and one or more other fields 604 of one or more sizes N, where N>M, to store uncompressed event data. However, it is not necessary that compressed event record 216A and uncompressed event record 216B comprise 1-bit compression field 502, 602 as part of the event record. It is also possible that a compression indicator field may reside outside of the event record. For example, the compression indicator field may reside in a header of the event buffer.

Compression

“Compression” as used herein means to reduce the size of data. In one embodiment, characteristics-based compression may be utilized to compress event data to help achieve optimal compression results.

### Characteristics-Based Compression

Characteristics-based compression is compression of an event datum based, at least in part, on one or more characteristics of the event datum. A “characteristic” of an event datum means a feature of the event datum, such as redundancies in one or more bits of the event datum, accuracy of the event datum required by a client application, or size of the event datum, for examples.

Event data may include, for example, address information, such as an instruction address that may correspond to an address of an instruction that may result, at least in part, in an instruction cache miss, a data address that may correspond to an address of an accessed memory location that may result, at least in part, in a cache miss, or a branch/target address that may correspond to an address of a branch instruction, and an address of a branch target in a branch event. Since each address (i.e., event data) may exhibit one or more different characteristics, the compression algorithm that may be used to compress each address (i.e., event data) may differ. Of course, event data other than addresses may be compressed based, at least in part, on one or more of characteristics of the event data. Furthermore, characteristics-based compression is not necessarily limited to event data.

For example, since instruction addresses may frequently recur in instruction cache miss events, an instruction address compression algorithm may compress the lower set of bundle address bits. Such a compression algorithm may effectively compress instruction addresses because certain events, such as data and instruction cache misses, typically occur at only a relatively small number of instructions. In contrast, data addresses may rarely recur in data cache miss events. Consequently, compression of data addresses may differ from instruction addresses. For example, a data address compression algorithm may compress the upper address bits, which tend to recur frequently because application data references cluster around a few memory regions. As another example, some event data can afford lossy compression, such as latency data. Such event data may be compressed by a compression algorithm that quantizes uncompressed latency data into a bin that may represent a range of values rather than a single value.

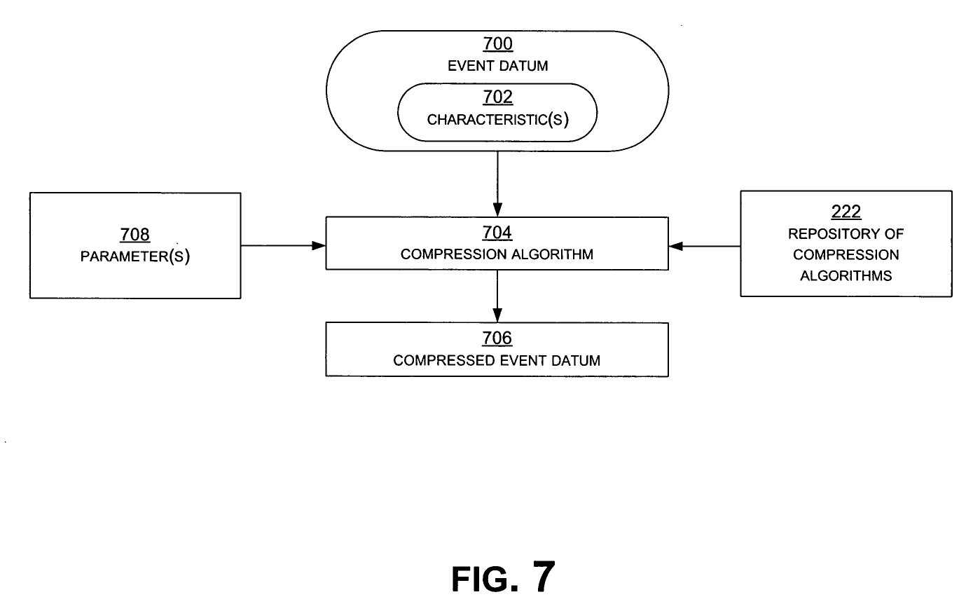

For any given event datum, the event datum 700 may be compressed based, at least in part, on one or more characteristics 702 of the event datum by using a selected compression algorithm 704 of one or more compression algorithms, as illustrated in FIG. 7. In one embodiment, the compression algorithm 704 may be selected from a repository of compression algorithms 222. However, embodiments of the invention are not limited to selecting compression algorithms 704. For example, if a single compression algorithm 704 is used, the compression algorithm 704 may not need to be selected. Each compression algorithm 704 may correspond to a particular event datum. A compression algorithm 704 that corresponds to an event datum may be a compression algorithm 704 that may be tailored to compress the event datum based, at least in part, on one or more characteristics of the event datum. Compression algorithms 704 need not correspond to event data. It is also possible that any given compression algorithm 704 may be used for a plurality of event data if, for example, the event data have one or more characteristics in common.

### Setting Compression Algorithms

A compression algorithm 704 may include one or more parameters 708 that may enable the compression algorithm 704 to be used on event data for different client applications 212 and/or for different purposes. For example, one client application 212 may need a 10-bit compressed instruction address, while another client application 212 may need a 16-bit compressed instruction address. Thus, one parameter 708 in an instruction address compression algorithm 702 may be the size of the compressed instruction address, for example.

Other parameters 708 may comprise, for example, size of instruction address dictionary (which may be a function of the size of compressed instruction address); size of data address dictionary (and, therefore, size of compressed data address); size of latency field; record format, including event record layout; and portions of event data to be compressed (e.g., upper 5 bits of the address, lower 10 bits of a bundle portion of the address).

In one embodiment, performance monitor driver 208 may use the one or more parameters 708 to set one or more compression algorithms 704 to perform characteristics-based compression. To “set”, as used herein, means to arrange, organize, layout, modify, and/or program for use. In embodiments of the invention, performance monitor driver 208 may set one or more compression algorithms 704 by providing information (e.g., one or more parameters 708) to one or more compression algorithms 704 that may enable one or more compression algorithms 704 to compress event data in accordance with the provided information. Alternatively, it can be said that performance monitor driver 208 may use one or more parameters 708 to set one or more compressors 210. For example, one or more parameters 708 may be provided to a compressor 210, where the compressor 210 corresponds to a specific compression algorithm 704. As another example, system 200 may comprise a plurality of compressors, each compressor corresponding to a compression algorithm 704, such that one or more parameters 708 used to set compressor 210 are the one or more parameters 708 used to set a compression algorithm 704. As used herein, setting of a compression algorithm 704 shall also mean setting of a compressor 210.

In one embodiment, a default setting mode may be used. In default setting mode, performance monitor driver 208 may determine one or more values for one or more parameters to provide to one or more compression algorithms. This may be done, for example, when the performance monitor driver 208 is initialized. In default mode, for example, values for parameters in a data cache miss event, for example, may be specified by performance monitor driver 208 as follows:
A 1024 (2\hat{ }10) entry instruction address dictionary, and a 10-bit compressed instruction address.

A 524288 (2\hat{ }19) entry data address dictionary, and a 19-bit compressed data address.

A 2-bit compressed latency data field to map latency data into one of 4 buckets.

A 1-bit field to indicate one of two types of processed event records 216 (2\hat{ }1-bit=2) (e.g., compressed event record 210A or uncompressed event record 210B). Alternatively, for example, a 2-bit field may be specified to indicate one of up to four types of processed event records 216 (2\hat{ }2-bit=4) (e.g., compressed event record 210A, uncompressed event record 210B, or hybrid event record 210C).

A record format and layout, such as illustrated in FIGS. 5 and 6.

Compress the lower set of bundle address bits of instruction addresses.

Compress the upper bits of data addresses.

In another embodiment, a client mode may be used. In client mode, client application 212 may determine one or more values for one or more parameters. Client application 212 may communicate these values to performance monitor driver 208. This may be done, for example, when client application 212 requests services from PMU 204. Client mode may be used, for example, where client application 212 may have better knowledge of the types of events being monitored, and characteristics of those events. For example, client application 212 may know that a particular event is associated with a large instruction address, and a small data address. Therefore, rather than use a default instruction address dictionary size and data address dictionary size, client application 212 may want to specify a larger instruction address dictionary size, and a smaller data address dictionary size. Furthermore, client application 212 may decide that it has no use for latency data, so it may request that the performance monitor driver 208 throw out the latency data.

In client mode, for example, values for parameters in a data cache miss event, for example, may be specified by client application 212 as follows:

A 32768 (2\hat{ }15) entry instruction address dictionary, and a 15-bit compressed instruction address.

A 65536 (2\hat{ }16) entry data address dictionary, and a 16-bit compressed data address.

A 0-bit compressed latency field.

A 1-bit field to indicate one of two types of processed event records 216 (2\hat{ }1-bit=2) (e.g., compressed event record 210A or uncompressed event record 210B). Alternatively, for example, a 2-bit field may be specified to indicate one of up to four types of processed event records 216 (2\hat{ }2-bit=4) (e.g., compressed event record 210A, uncompressed event record 210B, or hybrid event record 210C).

A record format and layout, such as illustrated in FIGS. 5 and 6.

Compress the lower set of bundle address bits of instruction address.

Compress the upper bits of data addresses.

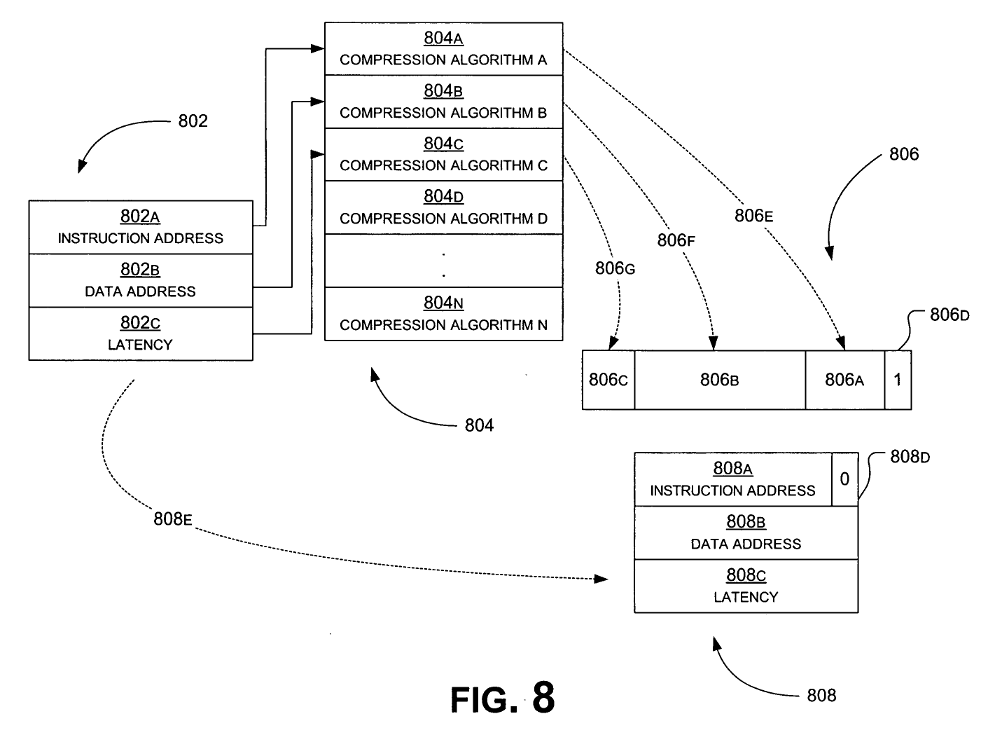

FIG. 8 illustrates an example of characteristics-based compression of an event record. An unprocessed event record 802 may comprise a field for an instruction address 802A, a field for a data address 802B, and a field for latency data 802C. Each event datum (i.e., instruction address 802A, data address 802B, and latency data 802C) may be compressed using a selected compression algorithm 804, such as may be in repository of compression algorithms 222. In this example, compression algorithm A (804A) may be used to compress the instruction address 802A; compression algorithm B (804B) may be used to compress the data address 802B; and compression algorithm C (804C) may be used to compress the latency data 802C.

The example illustrates the use of one of two record formats. A compressed record format, such as compressed record format 500, may be used in a compressed event record 806, such as 21 6A. Alternatively, an uncompressed record format, such as uncompressed record format 600, may be used in an uncompressed event record 808, such as 216B. This example does not illustrate the alternative use of a hybrid record format in a hybrid event record 21 6C.

In one embodiment, if instruction address 802A, data address 802B, and latency data 802C can all be compressed using compression algorithms A (804A), B (804B), and C (804C), respectively, then compressed event record 806 may be generated. A 1-bit field 806D may indicate that the event record is compressed. In this embodiment, compression algorithm A (804A) may output 806E compressed instruction address 806A; compression algorithm B (804B) may output 806F compressed data address 806B; and compression algorithm C (804C) may output 806G compressed latency data 806C.

Alternatively, if instruction address 802A, data address 802B, and latency data 802C cannot all be compressed using compression algorithms A (804A), B (804B), and C (804C), respectively, then an uncompressed event record 808 may be generated. A 1-bit field 808D may indicate that the event record is uncompressed. In this embodiment, uncompressed event record 808 comprising uncompressed instruction address 808A, uncompressed data address 808B, and uncompressed latency data 808C may be outputted 808E.

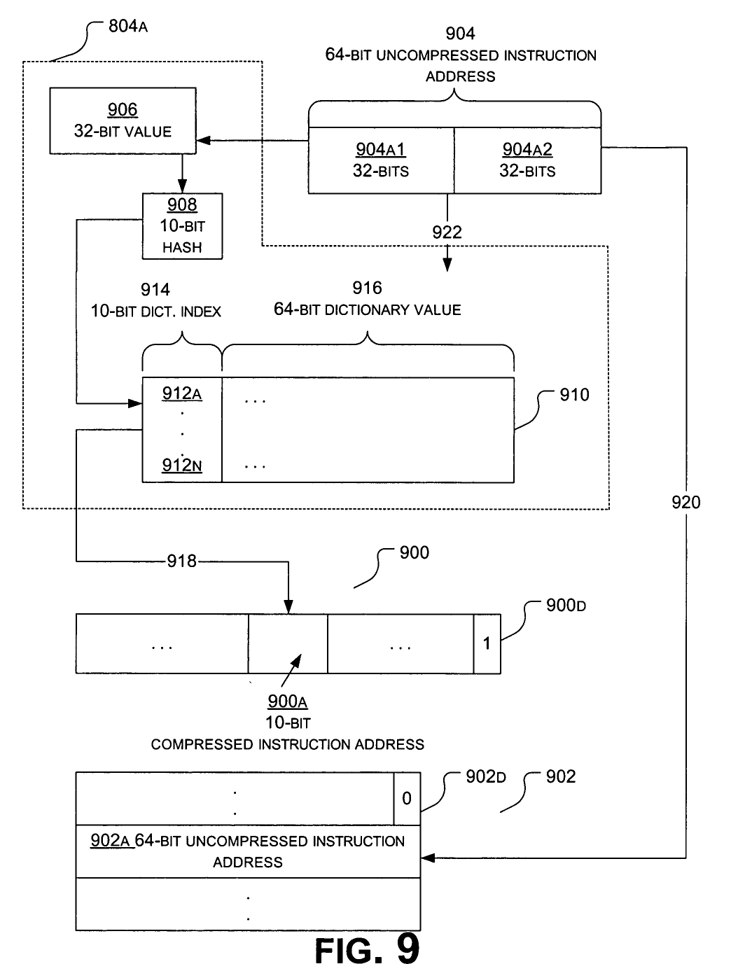

FIG. 9 illustrates an example of characteristics-based compression of an instruction address. FIG. 9 illustrates compression of 64-bit uncompressed instruction address 904 by an instruction address compression algorithm 804A into either a compressed event record 900 having a 10-bit compressed instruction address 900A, or an uncompressed event record 902 having a 64-bit uncompressed instruction address 902A. In this example, instruction address compression algorithm 804A may compress 64-bit uncompressed instruction address 904 as follows:

1. A portion of the 64-bit uncompressed instruction address 904 may be used to generate a 10-bit hash 908 using a hash function of compression algorithm 804A. In this example, the 64-bit uncompressed instruction address 904 may comprise a 64-bit bundle address, including a 2-bit instruction slot number, where the 64-bit bundle address may comprise an upper 32-bits 904A1 and a lower 32-bits 904A2. Also in this example, the lower set of bits of the bundle address, in this case, a 32-bit value 904A2, may be used as the value 906 to compress. For simplicity, the 2 part address may be referred to as a 64-bit instruction address 904.

2. Map the 10-bit hash 908 to a 10-bit dictionary index 914 in an instruction address dictionary 910. Instruction address dictionary 910 may comprise one or more entries 912A . . . 912N, where each entry 912A . . . 912N may comprise a 10-bit dictionary index 914, and a 64-bit dictionary entry 916.

As used herein, “map” means to use a first value to obtain a second value. In one embodiment, direct mapping of the first value to the second value may be used. Direct mapping means that the first value may have a one-to-one correspondence with the second value. For example, in this embodiment, the 10-bit hash 908 (first value) is matched to a 10-bit dictionary index 914 in an address dictionary 910 to obtain a 64-bit dictionary entry 916 (second value). However, it is also possible to use set associative mapping, fully associative mapping, or pseudo associative mapping without departing from embodiments of the invention.

In set associative mapping, the hash of a value may return a set index, where each entry corresponding to a set index may be checked. A “set index”, in the context of mapping, refers to entries within a set (corresponding to the set index) that may have the index (of the set index) as its prefix. The set size and the number of values within the set may depend on the prefix size and the dictionary size. For example, if the dictionary size is 512 entries, and the prefix size is 7 bits, then there may be 128 sets (2\hat{ }7), each of which may comprise four entries (128*4=512). Each of the four entries may be checked for addresses that hash to the set.

In fully associative mapping, the hash of a value may return a set index that may map to each entry in a dictionary. In pseudo associative mapping, if a hash of a value does not result in an entry that corresponds to the event datum (see below), then one or more rehash functions may be used check one or more corresponding subsequent entries.

3. If the 64-bit dictionary entry 916 corresponds to the 64-bit uncompressed instruction address 904, then output 918 to compressed event record 900 a 10-bit compressed instruction address 900A equivalent to the 10-bit hash 908. In this example, the 64-bit dictionary entry 916 “corresponds to” the 64-bit uncompressed instruction address 904 if the 64-bit dictionary entry 916 matches the 64-bit uncompressed instruction address 904. However, embodiments of the invention should not be limited to any particular type of correspondence. Compression field 900D may indicate that the event record is compressed (set to “1”, for example).

4. If the 64-bit dictionary entry 916 does not match the 64-bit value 904, then:

a. Output 920 to uncompressed event record 902 a 64-bit uncompressed instruction address 902A equivalent to 64-bit uncompressed instruction address 904. Compression field 902D may indicate that the event record is uncompressed (set to “0”, for example).

b. Replace 922 the 64-bit dictionary entry 916 with the 64-bit value 904 at the entry 912A . . . 912N corresponding to the 10-bit hash 908.

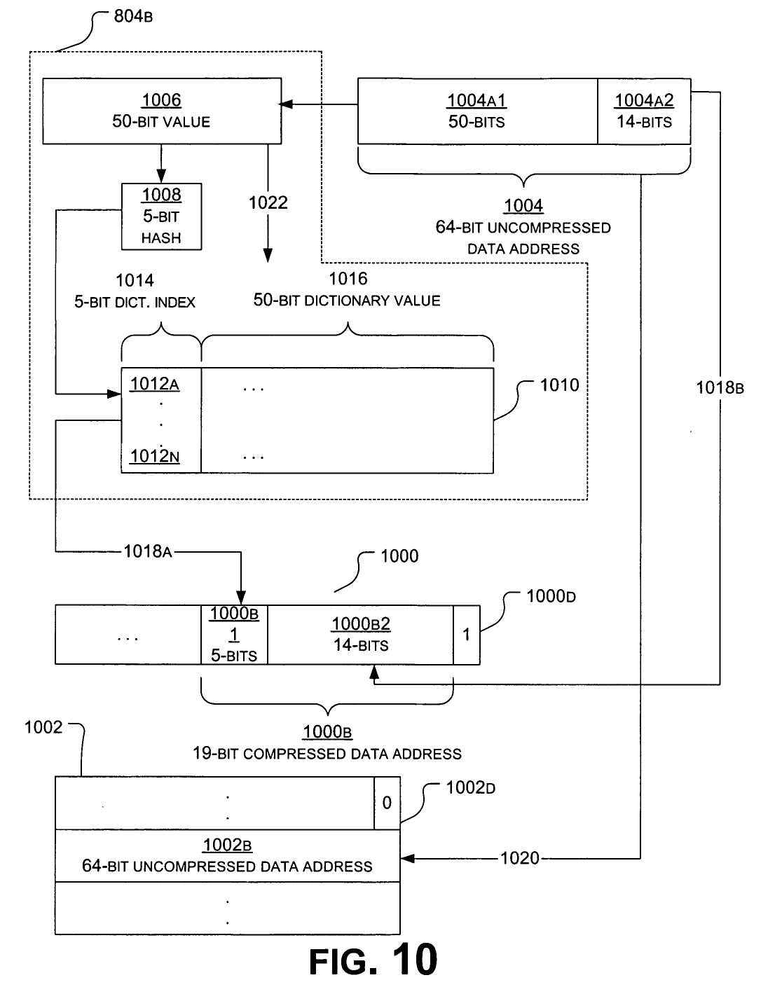

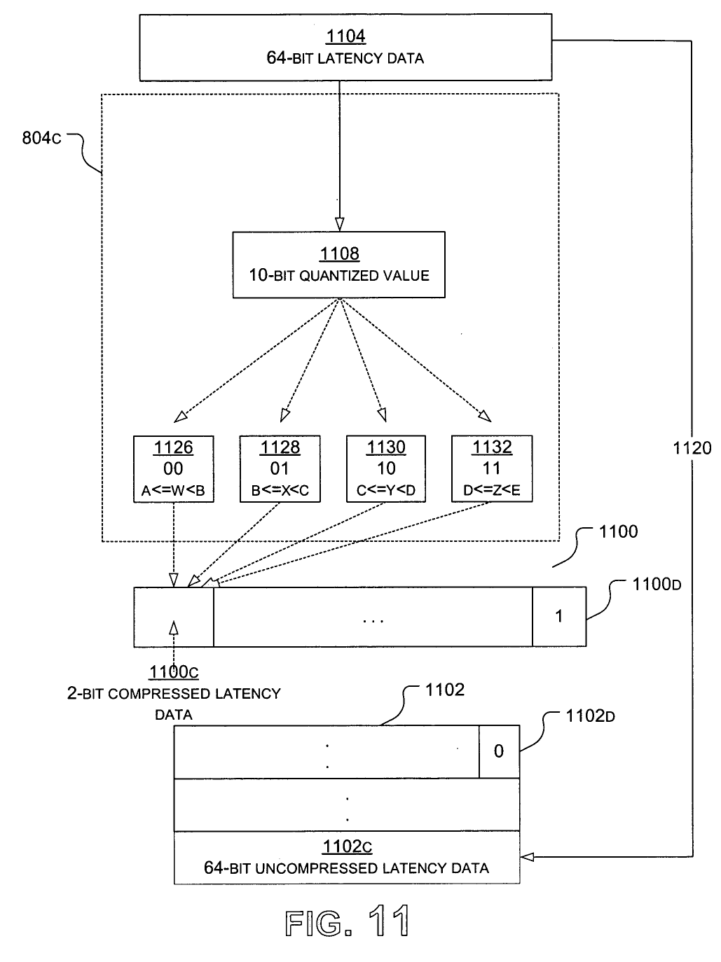

FIG. 10 illustrates an example of characteristics-based compression of a data address. FIG. 10 illustrates compression of a 64-bit uncompressed data address 1004 by a data address compression algorithm 804B into either a compressed event record 1000 having a 19-bit compressed data address 1000B (comprising a 5-bit compressed data 1000B1 of the 50 upper bits, and a 14-bit uncompressed data 1004B2 of the 14-bit uncompressed data 1004A2 of the 64-bit uncompressed data address 1004), or an uncompressed event record 1002 having a 64-bit uncompressed data address 1002B. In this example, data address compression algorithm 804B may compress 64-bit uncompressed data address 1004 as follows:

1. A portion of the 64-bit uncompressed data address 1004 may be used to generate a 5-bit hash 1008 using a hash function of compression algorithm 804B. In this example, the 64-bit uncompressed instruction address 904 may be comprised of an upper 50-bit portion 1004A1 and a 14-bit 1004A2 lower portion, and the upper portion 1004A1 of the address 1004, in this case, a 50-bit value 1006, may be used as the value to compress. The remaining bits, 14-bits 1004A2, of the 64-bit data address 1004 are not used to generate the 5-bit hash 1008 in this example.

2. Map the 5-bit hash 1008 to a 5-bit dictionary index 1014 in a data address dictionary 1010. Data address dictionary 1010 may comprise one or more entries 1012A . . . 1012N, where each entry 1012A . . . 1012N may comprise a 5-bit dictionary index 1014, and a 50-bit dictionary entry 1016.

3. If the 50-bit dictionary entry 1016 corresponds to the 64-bit uncompressed data address 1004, then output 1018A to compressed event record 1000 a 5-bit value equivalent to the 5-bit hash 1008. In this example, the 50-bit dictionary entry 1016 “corresponds to” the 64-bit uncompressed data address 1004 if the 50-bit dictionary entry 1016 matches the 50-bit value 1006 derived from the 50-bit portion 1004A1 of the 64-bit uncompressed data address 1004. However, embodiments of the invention should not be limited to any particular type of correspondence. In this example, the 14-bit 1004A2 lower portion of the 64-bit uncompressed data address 1004 may be appended to the 5-bit compressed value to generate the 19-bit compressed data address 1000B. Compression field 1000D may indicate that the event record is compressed (set to “1”, for example).

4. If the 50-bit dictionary entry 1016 does not match the 50-bit value 1006, then:

a. Output 1020 to uncompressed event record 1002 a 64-bit uncompressed instruction address 1002B equivalent to 64-bit uncompressed instruction address 1004. Compression field 1002D may indicate that the event record is uncompressed (set to “0”, for example).

b. Replace 1022 the 50-bit dictionary entry 1016 with the 50-bit value 1006 at the entry 1012A . . . 1012N corresponding to the 5-bit hash 1008.

FIG. 11 illustrates an example of characteristics-based compression of latency data. FIG. 11 illustrates compression of 64-bit latency data 1104 by a latency data compression algorithm 804C into either a compressed event record 1100 having 2-bit compressed latency data 1100C, or uncompressed event record 1102 having 64-bit uncompressed latency data 1102C.

In this example, latency data may be compressed by latency data compression algorithm 804C by quantizing the 64-bit latency data 1104 into 10-bit quantized value 1108. The 10-bit quantized value 1108 may fall into one of 4 (2 bits\hat{ }2) buckets 1126, 1128, 1130, 1132, where each bucket 1126, 1128, 1130, 1132 may store a range of values. For example, bucket 1126 may store values W, where A<=W<B; bucket 1128 may store values X, where B<=X<C; bucket 1130 may store values Y, where C<=Y<D; and bucket 1132 may store values Z, where D<=Z<E. Each bucket 1126, 1128, 1130, 132 may correspond to a bucket number, 00, 01, 10, 11, and each bucket number 00, 01, 10, 11 may be used as the 2-bit compressed latency data 1100C in compressed event record 1100 indicated by compression field 1100D (set to “1”, for example).

Thus, if the 10-bit quantized value, X, is greater than B, but less than C, then the 10-bit quantized value, X, may belong in bucket 1128, which corresponds to bucket number 01. The 2-bit bucket number, 01, may be used as the 2-bit compressed latency data 1100C in compressed event record 1100. Alternatively, uncompressed event record 1102 may be used to store 64-bit uncompressed latency data 1102C, where uncompressed event record 1102 may be indicated by compression field 1102D (set to “0”, for example).

As another example of characteristics-based compression, which is not illustrated, branch and target instruction address pairs in branch events may be compressed by a branch event compression algorithm. As an example of compression of this type of event, a branch address dictionary may be maintained, where each dictionary entry corresponds to an address pair. The address pair may be obtained by hashing the branch address and target address into a single address. The hashing scheme may XOR (exclusive OR) the branch address with the target address to form the single address, or may use a subset of bits from the branch and a subset of bits from the target address to form the single address. The resulting address may be mapped to a dictionary index.

While examples of compression have been illustrated for specific event data, the examples of compression are not limited to the particular event data illustrated, nor are they limited to the particular field and compression sizes illustrated. The examples of compression may be utilized on other types of event data that may exhibit similar or different characteristics than the event data illustrated. Furthermore, compression may be achieved in other ways not described herein without departing from embodiments of the invention. Likewise, other compression algorithms may be used.

Decompression

Client application 212 may read one or more event records from event buffer 204. In one embodiment, performance monitor driver 208 may notify client application 212 when event buffer 204 is full. Client application 212 may read each event record in event buffer 204. For each event datum, if the event datum is compressed, decompressor 214 may decompress the event datum to generate client uncompressed event datum 220. If the event datum is not compressed, the event datum may be used as the client uncompressed event datum 220. Event buffer 204 may maintain information about address dictionary, such as the size, organization, and hash function used. Decompressor 214 may maintain a copy of address dictionary 910, 1010 separately from compressor 210.

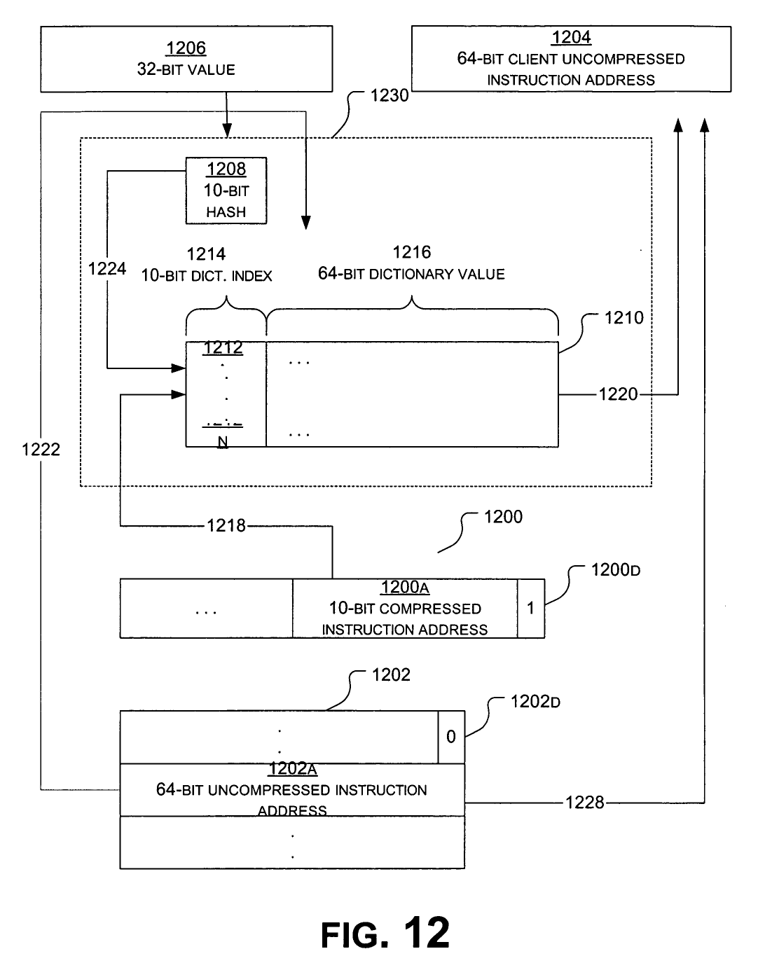

FIG. 12 illustrates an example of event record processing by client application 212. If event record is an uncompressed event record 1202, indicated by compression field 1202D (set to “0”, for example), client application 212 may output 1228 the 64-bit uncompressed instruction address 1202A from uncompressed event record 1202 as the 64-bit client uncompressed instruction address 1204.

Furthermore, client application 212 may generate a 10-bit hash from a 32-bit value 1206 that was used for compression. Client application 212 may know the 32-bit value 1206 to be compressed either because performance monitor driver 208 may make that information available to client applications 212, or because such information was requested by client application 212. The 10-bit hash 1208 may be indexed 1224 to a 10-bit dictionary index 1214 of an instruction address dictionary 1210 having one or more entries 120A . . . 1212N, where each entry may correspond to a 10-bit dictionary index 1214, and a 64-bit dictionary entry 1216. The 64-bit value 1202A may then be used 1226 as the 64-bit dictionary entry 1216 at the entry corresponding to the 10-bit hash 1214.

If event record is a compressed event record 1200, indicated by compression field 1200D (set to “1”, for example), client application 212 may decompress the 10-bit compressed instruction address 1200A in compressed event record 1200 using an instruction address decompression algorithm 1230 (such as may be used by decompressor 214) as follows:

1. Map 1218 the 10-bit compressed instruction address 1200A to a 10-bit dictionary index 1214 of an address dictionary 1210.

2. Output 1220 the 64-bit dictionary entry 1216 as the 64-bit client uncompressed instruction address 1204.

Similar decompression algorithms may be used for other types of event data. For example, this decompression algorithm may be used on a data address having a 5-bit compressed data address and a 5-bit dictionary index.

Conclusion

Therefore, in one embodiment, a method may comprise reading one or more event data, the one or more event data corresponding to an event monitored from a system; for each event datum, compressing the event datum if the event datum is determined to be compressible; creating a processed event record, the processed event record conforming to a record format; and storing the one or more event data in the processed event record in accordance with the record format.

Embodiments of the invention may reduce overhead associated with performance monitoring. Overhead, such as inter-process communication, and event buffers, may be reduced as a result of compressing event records. For example, since event records may be compressed, event buffer size may be reduced. Embodiments of the invention may also enable client applications that utilize performance events to optimize more effectively. Since event records is determined to be compressible, more event records can be stored in an event buffer, even if the size of the event buffer is reduced in some cases. Since more event records can be stored, more events may be made available to client applications. Consequently, client applications may have more event data available to them that can be used for optimization, and may reduce the frequency in which clients may be notified when the event buffer is full.

In the foregoing specification, the invention has been described with reference to specific embodiments thereof. It will, however, be evident that various modifications and changes may be made to these embodiments without departing therefrom. The specification and drawings are, accordingly, to be regarded in an illustrative rather than a restrictive sense.

1. A method comprising:
reading one or more event data, the one or more event data corresponding to an event monitored from a system;
for each event datum, compressing the event datum if the event datum is determined to be compressible;
creating a processed event record, the processed event record conforming to a record format; and
storing the one or more event data in the processed event record in accordance with the record format.

2. The method of claim 1, wherein said creating a processed event record and storing the one or more event data in the processed event record in accordance with the record format comprises one of the following:
if one or more of the one or more event data is determined not to be compressible, then:
creating an uncompressed event record in an uncompressed record format; and
storing each event datum in an uncompressed format in the uncompressed event record;
if each of the one or more event data is determined to be compressible, then:
creating a compressed event record in a compressed record format; and
storing each event datum in a compressed format in the compressed event record; and
if one or more of the one or more event data is determined not to be compressible, then:
creating a hybrid event record in a hybrid record format; and
storing each uncompressed event datum in an uncompressed format in the hybrid event record, and storing each compressed event datum in a compressed format in the hybrid event record.

3. The method of claim 1, wherein said compressing each event datum comprises characteristics-based compression.

4. The method of claim 3, wherein the characteristics-based compression comprises using a selected one of one or more compression algorithms to compress the event datum, wherein the selected compression algorithm compresses the event datum in accordance with one or more characteristics of the event datum.

5. The method of claim 4, additionally comprising setting the one or more compression algorithms.

6. The method of claim 3, wherein the characteristics-based compression algorithm comprises for at least one of the one or more event data:
generating a hash from a value, the value based, at least in part, on one or more characteristics of a given event datum of the at least one of the one or more event data;
mapping the hash to a dictionary index in a dictionary, the index corresponding to a dictionary entry; and
if the dictionary entry corresponds to the given event datum, then outputting the dictionary index.

7. The method of claim 6, additionally comprising if the dictionary entry does not correspond to the given event datum, then outputting the given event datum.

8. A method comprising:
reading one or more processed event records from an event buffer, each processed event record including one or more processed event data corresponding to one or more uncompressed event data; and
generating one or more client uncompressed event data corresponding to the one or more uncompressed event data, said generating one or more client uncompressed event data including one of:
decompressing an event datum if the event datum is in a compressed format; and
outputting an event datum if the event datum is not in a compressed format.

9. The method of claim 8, wherein said decompressing the event datum comprises:
mapping a plurality of bits of the event datum to a dictionary index in a dictionary, each entry in the address dictionary including a dictionary index and a corresponding dictionary entry; and
using the dictionary entry to obtain the one or more uncompressed event datum.

10. The method of claim 9, wherein if the event datum is not in a compressed format:
generating a hash value from a compression value, the compression value based, at least in part, on the event datum;
mapping the hash value to a dictionary index in a dictionary having one or more entries, each entry corresponding to a hash value and a dictionary entry;
replacing the dictionary entry with the compression value, said replacing occurring at an entry of the dictionary corresponding to the hash value.

11. An apparatus comprising:
circuitry capable of:
reading one or more event data, the event data corresponding to an event monitored from a system;
for each event datum, compressing the event datum if the event datum is determined to be compressible;
creating a processed event record, the processed event record conforming to a record format; and
storing the one or more event data in the processed event record in accordance with the record format.

12. The apparatus of claim 11, wherein said circuitry is further capable of using characteristics-based compression on each event datum.

13. The apparatus of claim 12, wherein said circuitry is further capable of using a selected one of one or more compression algorithms to compress the event datum, wherein the selected compression algorithm compresses the event datum in accordance with one or more characteristics of the event datum.

14. The apparatus of claim 13, wherein said circuitry is further capable of setting the one or more compression algorithms.

15. A system comprising:
circuitry capable of:
reading one or more event data, the event data corresponding to an event monitored from a system;
for each event datum, compressing the event datum if the event datum is determined to be compressible;
creating a processed event record, the processed event record conforming to a record format; and
storing the one or more event data in the processed event record in accordance with the record format; and
a compiler to read the processed event record.

16. The system of claim 15, wherein said circuitry is further capable of using characteristics-based compression on each event datum.

17. The system of claim 16, wherein said circuitry is further capable of using a selected one of one or more compression algorithms to compress the event datum, wherein the selected compression algorithm compresses the event datum in accordance with one or more characteristics of the event datum.

18. The system of claim 17, wherein said circuitry is further capable of setting the one or more compression algorithms.

19. A machine-readable medium having stored thereon instructions, the instructions when executed by a machine, result in the following:
reading one or more event data, the event data corresponding to an event monitored from a system;
for each event datum, compressing the event datum if the event datum is determined to be compressible;
creating a processed event record, the processed event record conforming to a record format; and
storing the one or more event data in the processed event record in accordance with the record format.

20. The machine-readable medium of claim 19, wherein said instructions, when executed by the machine, additionally result in the machine using characteristics-based compression on each event datum.

21. The machine-readable medium of claim 20, wherein said instructions, when executed by the machine, additionally result in the machine using a selected one of one or more compression algorithms to compress the event datum, wherein the selected compression algorithm compresses the event datum in accordance with one or more characteristics of the event datum.

22. The machine-readable medium of claim 21, wherein said instructions, when executed by the machine, additionally result in the machine setting the one or more compression algorithms.
